(19) United States
(12) Patent Application Publication
(10) Pub. No.: US 2025/0372504 A1
(43) Pub. Date: Dec. 4, 2025

(54) FET WITH BACKSIDE POWER DISTRIBUTION NETWORK AND CAPACITOR

(71) Applicant: International Business Machines Corporation, Armonk, NY (US)

(72) Inventors: Manasa MEDIKONDA, ALBANY, NY (US); Tao Li, Slingerlands, NY (US); Ruilong Xie, Niskayuna, NY (US); Joshua M. Rubin, Albany, NY (US); Mukta Ghate Farooq, Hopewell Junction, NY (US)

(21) Appl. No.: 18/678,751

(22) Filed: May 30, 2024

(51) Int. Cl. H01L 23/522; H01L 23/00; H01L 23/528; H01L 27/088; H01L 29/06; H01L 29/423; H01L 29/775; H01L 29/786

(52) U.S. Cl. CPC H01L 23/5223; H01L 23/5286; H01L 24/08; H10D 30/43; H10D 30/6735; H10D 30/6757; H10D 62/121; H10D 84/83; H01L 2224/08145

(57) ABSTRACT

A semiconductor device is provided that includes a non-stacked field effect transistor (FET) or a stacked FET with at least one capacitor and a backside power distribution network. The at least one capacitor is configured for power delivery, analog applications or when two capacitors are present one of the capacitors is configured for power delivery and the other capacitor is configured for analog applications.

### BACKGROUND

The present application relates to semiconductor technology, and more particularly to a semiconductor device including a non-stacked field effect transistor (FET) or stacked FET in which a capacitor and a backside power distribution network is present.

Transistors are the building blocks of modern electronics, enabling everything from smartphones to supercomputers. In the latter half of the 20th century, planar transistors dominated. Planar transistors feature a gate stack situated above a channel region. By applying a voltage to the gate stack, a layer of mobile charge carriers formed in the channel region, allowing current to flow between a source region and a drain region. However, as area and power consumption has been scaled, planar transistor have encountered limitations.

Around the early 2010s, a transition from planar transistors to non-planar transistors such as, for example, fin-shaped transistors referred to as finFETs, began. FinFETs allow for better control of current flow and improved performance. Yet even these fin-shaped transistors have their limits.

To overcome the limits in planar and finFET transistors, three dimensional (3D) stacked transistors have been recently investigated. A 3D stacked transistor includes one transistor stacked above another transistor. In some applications, the top and bottom devices are of complementary types: NMOS (n-type) and PMOS (p-type), forming the foundation of logic circuits. Such stacked transistors can provide logic that is 30 to 50 percent smaller than either planar or finFETs. Stacked transistors hold a promise of extending Moore's Law into the next decade.

Traditionally, semiconductor chips have power delivered from the frontside of the chip. This requires power to be delivered through multiple (e.g., over 10) layers of wiring, down to the transistor. There are two major limitations of this approach: valuable real estate on the chip must be allocated for power lines, and power is lost as it traverses the multiple levels down to the transistor.

Backside power delivery refers to the technique of routing power lines on the backside of a semiconductor chip or integrated circuit (IC) instead of the traditional frontside. This approach increases logic density and improves power and performance.

### SUMMARY

A semiconductor device is provided that includes a non-stacked FET or a stacked FET with at least one capacitor and a backside power distribution network. The at least one capacitor is configured for power delivery, analog applications or when two capacitors are present one of the capacitors is configured for power delivery and the other capacitor is configured for analog applications.

In one embodiment of the present application, the semiconductor device includes a first FET device including a first FET device frontside back-end-of-the-line (BEOL) structure located on a frontside of a first FET device front-end-of-the-line (FEOL) level, and a first FET device backside power distribution network located on a backside of the first FET device FEOL level, wherein the first FET device frontside BEOL structure includes at least one capacitor embedded therein; and a second FET device including a second FET device frontside BEOL structure located on a frontside of a second FET device FEOL level, and a second FET device backside power distribution network located on a backside of the second FET device FEOL level, wherein the first FET device is stacked above the second FET device and the first FET device frontside BEOL structure forms a hybrid bonding interface with the second FET device backside power distribution network, and wherein the at least one capacitor is connected to the second FET device at the hybrid bonding interface.

In another embodiment of the present application, the semiconductor device includes a first FET device including a first FET device frontside BEOL structure located on a frontside of a first FET device FEOL level containing at least one first FET, and a first FET device backside power distribution network located on a backside of the first FET device FEOL level; and a second FET device including a second FET device frontside BEOL structure located on a frontside of a second FET device FEOL level containing at least one second FET, and a second FET device backside power distribution network located on a backside of the second FET device FEOL level, wherein the first FET device is stacked above the second FET device, the first FET device frontside FET device BEOL structure forms a hybrid bonding interface with the second FET device backside power distribution network, and the second FET device power distribution network includes at least one capacitor embedded therein, wherein the at least one capacitor is connected to the first FET device at the hybrid bonding interface.

In yet a further embodiment of the present application, the semiconductor device includes a frontside BEOL structure located on a frontside of a FEOL level containing at least one FET, and a backside power distribution network located on a backside of the FEOL level. The semiconductor device further includes at least one capacitor embedded in the frontside BEOL structure that is electrically connected to an upper frontside BEOL line and a lower frontside BEOL line, and at least one decoupling capacitor embedded in the backside power distribution network that is electrically connected to a backside power line of the backside power distribution network and a source/drain region of the at least one FET.

### BRIEF DESCRIPTION OF THE DRAWINGS

FIG. 1 is a cross sectional view of an exemplary first FET device that can be employed in the present application, the first FET device including a first FET device front-end-of-the-line (FEOL) level, a first FET device middle-of-the-line (MOL) level, and a first FET device frontside back-end-of-the-line (BEOL) structure, the first FET device frontside BEOL structure includes at least one capacitor embedded therein.

FIG. 2 is a cross sectional view of the an exemplary second FET device that can be employed in the present application, the second FET device including a second FET device FEOL level, a second FET device MOL level, and a second FET device frontside BEOL structure.

FIG. 3 is a cross sectional view of the exemplary second FET device of FIG. 2 after flipping the exemplary second FET device 180°, removing the substrate present in the second FET device FEOL level and forming a second FET device backside interlayer dielectric (ILD) layer.

FIG. 4 is a cross sectional view of the exemplary second FET device of FIG. 3 after forming second FET device backside source/drain contact structures in the second FET device backside ILD layer.

FIG. 5 is a cross sectional view of the exemplary second FET device of FIG. 4 after forming additional second FET device backside ILD layers with second FET device power lines embedded therein, wherein the additional second FET device backside ILD layers and the second device FET backside power lines collectively form a second FET device backside power distribution network.

FIG. 6 is a cross sectional view after forming a hybrid bonded structure by bonding the first FET device BEOL structure of the first FET device to the second FET device backside power distribution network utilizing a hybrid bonding process.

FIG. 7 is a cross sectional view of the hybrid bonded structure illustrated in FIG. 6 after removing the first substrate present in the first FET device FEOL level and forming a first FET device backside ILD layer.

FIG. 8 is a cross sectional view of the hybrid bonded structure illustrated in FIG. 7 after forming first FET device backside source/drain contact structures in the first FET device backside ILD layer.

FIG. 9 is a cross sectional view of the hybrid bonded structure shown in FIG. 8 after forming a first FET device backside power line and a first FET device backside power distribution network on the first FET device backside ILD layer.

FIG. 10 is a cross sectional view of an alternative hybrid bonded structure including a first FET device stacked above a second FET device in which the second FET device includes at least one capacitor instead of the first FET device as is shown in the hybrid bonded structure of FIG. 9.

FIG. 11 is a cross sectional view of another alternative hybrid bonded structure including a first FET device stacked above a second FET device in which the first FET device includes at least one capacitor and the second FET device includes at least one decoupling capacitor.

FIG. 12 is a cross sectional view of an exemplary device including a FET device including at least one decoupling capacitor located on the backside and at least one capacitor located on the frontside.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, or any combination of such FETs including nanosheet transistors. In some embodiments of the present application, a stacked FET is provided in which one FET device is stacked above another FET device.

In the present application, each FET device includes a frontside and a backside. The frontside includes a side of the FET device that includes at least one transistor, frontside contact structures, and a frontside BEOL structure. The backside of the FET device is the side of the device that is opposite the frontside. The backside includes backside contact structures, and a backside power distribution network.

In embodiments of the present application in which a stacked FET is provided, the stacking of one FET device on top of another FET will include the use of hybrid bonding. Notably, a frontside BEOL structure of one of the FET devices will be hybrid bonded to a backside power distribution network of another of the FET devices such that a hybrid bonding interface will be formed between the frontside BEOL structure of one of the FET devices and the FET backside power distribution network of another of the FET devices. The hybrid bonding interface will include dielectric-to-dielectric bonds and metal-to-metal bonds. The hybrid bonding interface will also be used to connect at least one capacitor that is present in one of the FET devices to the other FET device.

Throughout the present application, the term “hybrid bonding” refers to a 3D packing technique to connect semiconductor builds. Hybrid bonding forms connections of semiconductor structures through metal bond pads which are embedded in a dielectric layer at a bond interface on each semiconductor structure that is being bonded. The dielectric layer at bonding interface includes, but is not necessarily limited to, TEOS, SiO₂, SiCN, and/or SiCOH. The metal bond pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. Hybrid bonding process itself includes alignment to control the overlay of metal pads and to ensure electrical continuity between semiconductor build undergoing hybrid bonding process, mating of dielectric/metal pad surfaces, annealing under a set pressure. The anneal process of the mated semiconductor builds ensures formation of covalent bonds between the dangling bonds across the dielectric surfaces of opposing semiconductor builds, as well as reflow (melting and joining) of the metal pads between the surfaces of opposing semiconductor builds to ensure electrical conductivity. The covalent bonds formed between the dielectric surfaces, and the joining of metal pads as a result of reflow process ensures that hybrid bonding interfaces joins two semiconductor builds and also ensures that there is electrical continuity between them. The dangling bonds and covalent bonding occurs in the present application.

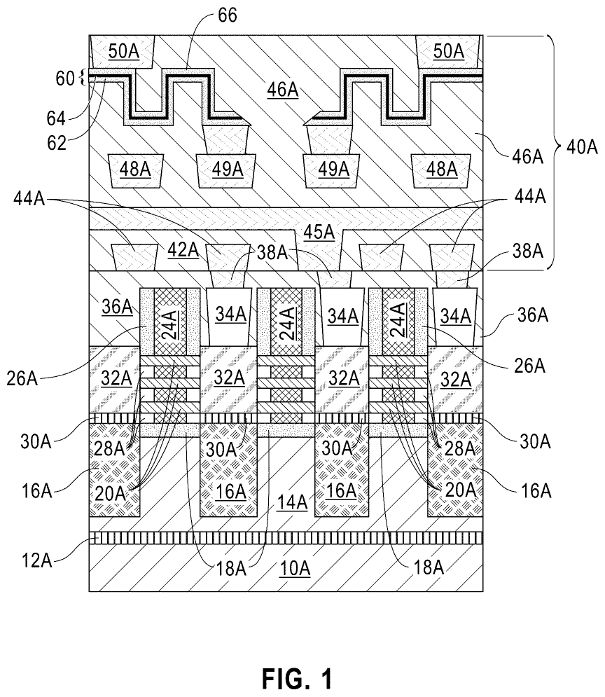

Reference is first made to FIG. 1, which illustrates an exemplary first FET device that can be employed in the present application. The first FET device includes a first FET device FEOL level, a first FET device MOL level, and a first FET device frontside BEOL structure 40A. In this embodiment, the first FET device frontside BEOL structure 40A includes at least one capacitor 60 embedded therein.

The first FET device FEOL level includes a first substrate and at least one first nanosheet transistor. The first FET device FEOL level can also include a first gate spacer 26A, a first inner spacer 28A, a first bottom dielectric isolation layer 18A, a first backside source/drain contact placeholder structure 16A, and a first semiconductor buffer layer 30A, as is shown in FIG. 1. In some embodiments, the first bottom dielectric isolation layer 18A and/or the first semiconductor buffer layer 30A can be omitted from the first FET device FEOL level. When present, the first bottom dielectric isolation layer 18A is located beneath each first nanosheet transistor. When present, the first semiconductor buffer layer 30A is present between the first backside source/drain contact placeholder structure 16A and a first source/drain region 32A of each first nanosheet transistor.

The first substrate can include a first semiconductor base layer 10A, a first etch stop layer 12A, and a first semiconductor device layer 14A. Embodiments are contemplated in which the first semiconductor base layer 10A and/or the first etch stop layer 12A are omitted and the first substrate includes only the first semiconductor device layer 14A. The first semiconductor base layer 10A is composed of a first semiconductor material, and the first semiconductor device layer 14A is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the first semiconductor device layer 14A can be compositionally the same as, or compositionally different from, the first semiconductor material that provides the first semiconductor base layer 10A.

In some embodiments of the present application, the first etch stop layer 12A can be composed of a dielectric material such as, for example, silicon dioxide and/or boron nitride. In other embodiments of the present application, the first etch stop layer 12A is composed of a third semiconductor material that is compositionally different from the first semiconductor material that provides the first semiconductor base layer 10A and the second semiconductor material that provides the first semiconductor device layer 14A. In one example, the first semiconductor base layer 10A is composed of silicon, the first etch stop layer 12A is composed of silicon dioxide, and the first semiconductor device layer 14A is composed of silicon. In another example, the first semiconductor base layer 10A is composed of silicon, the first etch stop layer 12A is composed of silicon germanium, and the first semiconductor device layer 14A is composed of silicon.

Each first nanosheet transistor includes a first gate structure 24A wrapped around a portion of a vertical stack of spaced apart first semiconductor channel material nanosheets 20A, and a first source/drain region 32A located on each side of the first gate structure 24A. In the illustrated embodiment, each first source/drain region 32A extends outward from an end wall of each of the first semiconductor channel material nanosheets 20A, and when the first semiconductor buffer layer 30A is present, each first source/drain region 32A extends upward from the first semiconductor buffer layer 30A.

Each first semiconductor channel material nanosheet 20A is composed of a fourth semiconductor material. In some embodiments, the fourth semiconductor material that provides each first semiconductor channel material nanosheet 20A can provide high channel mobility for n-type FET devices (i.e., NFETs). In other embodiments, the fourth semiconductor material that provides each first semiconductor channel material nanosheet 20A can provide high channel mobility for p-type FET devices (PFETs). The fourth semiconductor material that provides each first semiconductor channel material nanosheet 20A can include one of the semiconductor materials mentioned above. In one example, the fourth semiconductor material that provides each first semiconductor channel material nanosheet 20A is composed of silicon.

First gate structure 26A includes a first gate dielectric material and a first gate electrode, both of which are not separately shown, but intended to be within the region defined by the first gate structure 26A. As is known to those skilled in the art, a gate dielectric material directly contacts a physically exposed surface(s) of the semiconductor channel region (e.g., each first semiconductor channel material nanosheet 20A), and a gate electrode is formed on the gate dielectric material. The first gate dielectric material has a dielectric constant of 4.0 or greater. All dielectric constants mentioned herein are relative to a vacuum unless otherwise noted. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The first gate dielectric material can further include dopants such as lanthanum (La), aluminum (Al) and/or magnesium (Mg). The first gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

Each first source/drain region 32A is composed of a fifth semiconductor material and a first dopant. The fifth semiconductor material can be compositionally the same as, or compositionally different from the fourth semiconductor material that provides each first semiconductor channel material nanosheet 20A. The first dopant that is present in each first source/drain region 32A can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each first source/drain region 32A can have a dopant concentration of from 4×10²⁰ atoms/cm³ to 3×10²¹ atoms/cm³.

The first gate spacer 26A, the first inner spacer 28A and the first bottom dielectric isolation layer 18A are each composed of a spacer dielectric material. In present application, the first gate spacer 26A and the first bottom dielectric isolation layer 18A are typically composed of a same spacer dielectric material. Illustrative examples of spacer dielectric materials that can be used in providing the first gate spacer 26A, the first inner spacer 28A and the first bottom dielectric isolation layer 18A include, but are not limited to, silicon dioxide, silicon nitride, SiBCN, SiOCN or SiOC.

The first backside source/drain contact placeholder structure 16A which is present in an upper portion of the first substrate (e.g., the first semiconductor device layer 14A) includes a sixth semiconductor material. The sixth semiconductor material is compositionally different from the second semiconductor material that provides the first semiconductor device layer 14A. In one example, the sixth semiconductor material is a silicon germanium alloy. Note that the first backside source/drain contact placeholder structure 16A can extend above the topmost surface of the first semiconductor device layer 14A, but the height of the first backside source/drain contact placeholder structure 16A is typically less than, or equal to, a topmost surface of the first bottom dielectric isolation layer 18A.

If present, the first semiconductor buffer layer 30A is composed of a seventh semiconductor material that can be compositionally different from the sixth semiconductor material that provides the first backside source/drain contact placeholder structure 16A. The first semiconductor buffer layer 30A can be used as a growth surface for forming the first source/drain region 32A. Note that the first source/drain region 32A are typically formed by an epitaxial growth process and the presence of the first semiconductor buffer layer 30A facilitates the epitaxial growth of the first source/drain region 32A.

The first FET device FEOL level described above can be formed utilizing techniques (including nanosheet transistor formation techniques) well known to those skilled in the art. So as not to obscure any aspect of the present application details concerning the formation of the first FET device FEOL level are not provided herein.

The first FET device MOL level includes a first MOL dielectric layer 36A that includes at least one first FET device frontside source/drain contact structure 34A and at least one first MOL via contact structure 38A present therein. The first MOL dielectric layer 36A includes one or more interlayer dielectric (ILD) materials. Illustrative ILD materials that can be used in providing the first MOL dielectric layer 36A include, but are not limited to, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. The least one first FET device frontside source/drain contact structure 34A is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The least one first FET device frontside source/drain contact structure 34A can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. Each first FET device frontside source/drain contact structure 34A contacts a first source/drain region 32A as shown in FIG. 1.

The least first one MOL via contact structure 38A includes an electrically conductive metal or an electrically conductive metal alloy. Illustrative examples of electrically conductive metals that can be used include, but are not limited to, Cu, Al, Co, Ru, Mo, Os, Ir, or Rh. An illustrative electrically conductive alloy that can be used includes, but is not limited to, a Cu-Al alloy. Although not shown, a diffusion barrier liner can be present at least along the sidewall and optionally a bottom wall of the least one first MOL via contact structure 38A.

The first FET device MOL level described above can be formed utilizing techniques (including a metallization process) well known to those skilled in the art. So as not to obscure any aspect of the present application details concerning the formation of the first FET device MOL level are not provided herein.

Also present is the first FET device frontside BEOL structure 40A. The first FET device frontside BEOL structure 40A includes a first BEOL interconnect dielectric region 46A having first FET device frontside BEOL metal wiring and at least one capacitor 60 embedded therein. In the illustrated embodiment, two capacitors 60 are shown by way of one example. The first FET device frontside BEOL metal wiring includes first level BEOL lines 44A, a first combined BEOL wiring structure 45A (this includes a combination of one of the first level BEOL lines, a via structure and a second level BEOL line), nth level BEOL lines 48A (wherein n is greater than 3), second combined BEOL structures 49A (each includes a combination of one of the nth level BEOL metal lines and a metal via), and uppermost BEOL lines 50A. In the present application, the wiring within the BEOL structures are typically for signal delivery. In some embodiments of the present application and as illustrated, a first capacitor (e.g., the capacitor 60 shown, for example, on the left hand side of FIG. 1) is electrically connected to one of the uppermost BEOL lines 50A and one of the second combined BEOL structures 49A, and a second capacitor (the capacitor 60 shown, for example, on the right hand side of FIG. 1) that is also electrically connected to one of the uppermost BEOL lines 50A and one of the second combined BEOL structures 49A. Each capacitor 60 is embedded in an upper portion of the first BEOL interconnect dielectric region 46A. While the present application describes and illustrates capacitors that are joined directly to a BEOL line, the present application is not limited to just such a connection. For example, the capacitors could include two plates, and/or the vias could pass through the capacitor plates. See, for example, U.S. Pat. No. 9,627,312B2.

The first BEOL interconnect dielectric region 40A includes one or more interconnect dielectric material layers. The interconnect dielectric material layers can be composed of one of the ILD materials mentioned above. The first FET device frontside BEOL metal wiring is composed of an electrically conductive metal or an electrically conductive metal alloy, as defined above. Although not shown, a diffusion barrier liner can be present at least along the sidewall and optionally a bottom wall of the first FET device frontside BEOL metal wiring.

In the illustrated embodiment, each capacitor 60 is composed of a first metal layer 62, a capacitor dielectric layer 64, and a second metal layer 66. In some embodiments, the capacitor 60 can include more than two metal layers (i.e., plates). Also, and although the first metal layer 62 and the second metal layer 66 are illustrated as single layered, the present application contemplates embodiments in which multi-layered metal stacks can be used as the first metal layer 62 and/or the second metal layer 66. Further, although the capacitor dielectric layer 64 is illustrated as a single layer, the present application contemplates embodiments in which multi-layered dielectric stacks are employed as the capacitor dielectric layer. The first metal layer 62 is composed of a first conductive metal-containing material, while the second metal layer 66 is composed of a second conductive metal-containing material. The first conductive metal- containing material can be compositionally the same as, or compositionally different from, the second conductive metal-containing material. In the present application, the term “conductive metal-containing material” denotes a pure metal, a metal carbide compound or a metal nitride compound. Illustrative conductive metal-containing materials that can be used in providing the first metal layer 62 and the second metal layer 66 include, but are not limited to, titanium nitride and/or tantalum nitride. The capacitor dielectric layer 64 is composed of a dielectric material such as, for example, one of the high k gate dielectric materials mentioned above. Each capacitor 60 can be a 3D capacitor (i.e., metal-insulator-metal (MIM) capacitor) having a meandering (or serpentine) pattern to increase the overall surface area of the capacitor. 2D capacitors are also contemplated and can be used in the present application.

The first FET device frontside BEOL structure 40A described above can be formed utilizing techniques (including a BEOL process with capacitor formation including deposition and patterning) well known to those skilled in the art. So as not to obscure any aspect of the present application details concerning the formation of the first FET device frontside BEOL structure 40A are not provided herein.

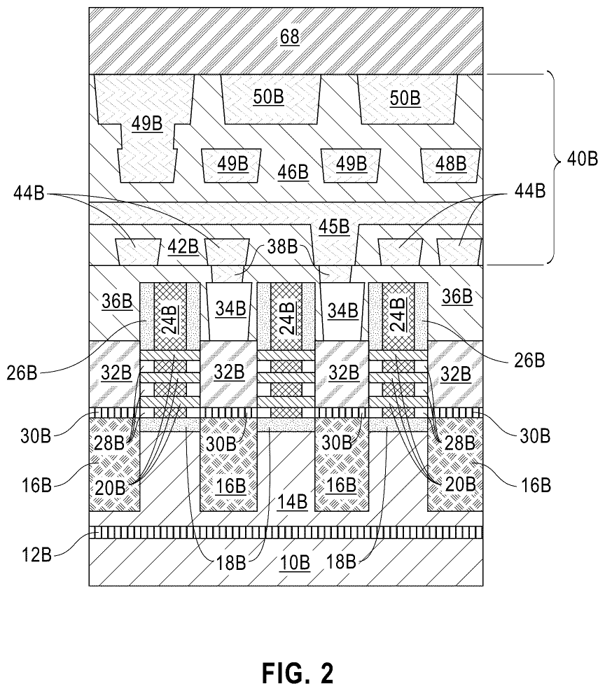

Referring now to FIG. 2, there is illustrated an exemplary second FET device that can be employed in the present application. The second FET device includes a second FET device FEOL level, a second FET device MOL level, and a second FET device frontside BEOL structure. The second FET device FEOL level includes a second substrate and at least one second nanosheet transistor. The at least one second nanosheet transistor typically, but not necessary always, is of a different conductivity type than the at least one first nanosheet transistor present in the first FET device FEOL level. The second FET device FEOL level can also include a second gate spacer 26B, a second inner spacer 28B, a second bottom dielectric isolation layer 18B, a second backside source/drain contact placeholder structure 16B, and a second semiconductor buffer layer 30B, as is shown in FIG. 2. In some embodiments, the second bottom dielectric isolation layer 18B and/or the second semiconductor buffer layer 30B can be omitted from the second FET device FEOL level. When present, the second bottom dielectric isolation layer 18B is located beneath each second nanosheet transistor. When present, the second semiconductor buffer layer 30B is present between the second backside source/drain contact placeholder structure 16B and a second source/drain region 32B of each second nanosheet transistor.

The second substrate can include a second semiconductor base layer 10B, a second etch stop layer 12B, and a second semiconductor device layer 14B. Embodiments are contemplated in which the second semiconductor base layer 10B and/or the second etch stop layer 12B are omitted and the second substrate includes only the second semiconductor device layer 14B. The second semiconductor base layer 10B is composed of an eighth semiconductor material, and the second semiconductor device layer 14B is composed of a ninth semiconductor material. The ninth semiconductor material that provides the second semiconductor device layer 14B can be compositionally the same as, or compositionally different from, the eighth semiconductor material that provides the second semiconductor base layer 10B.

In some embodiments of the present application, the second etch stop layer 12B can be composed of a dielectric material such as, for example, silicon dioxide and/or boron nitride. In other embodiments of the present application, the second etch stop layer 12B is composed of a tenth semiconductor material that is compositionally different from the eighth semiconductor material that provides the second semiconductor base layer 10B and the ninth semiconductor material that provides the second semiconductor device layer 14B. In one example, the second semiconductor base layer 10B is composed of silicon, the second etch stop layer 12B is composed of silicon dioxide, and the second semiconductor device layer 14B is composed of silicon. In another example, the second semiconductor base layer 10B is composed of silicon, the second etch stop layer 12B is composed of silicon germanium, and the second semiconductor device layer 14B is composed of silicon. In the present application, the second semiconductor base layer 10B and the first semiconductor base layer 10A can a compositionally same or a compositionally different semiconductor material, the second etch stop layer 12B and the first etch stop layer 10A can a compositionally same or a compositionally different semiconductor or dielectric material, and the second semiconductor device layer 14B and the second semiconductor device layer 14A can a compositionally same or a compositionally different semiconductor material.

Each second nanosheet transistor includes a second gate structure 24B wrapped around a portion of a vertical stack of spaced apart second semiconductor channel material nanosheets 20B, and a second source/drain region 32B located on each side of the second gate structure 24B. In the illustrated embodiment, each second source/drain region 32B extends outward from an end wall of each of the second semiconductor channel material nanosheets 20B, and when the second semiconductor buffer layer 30B is present, each second source/drain region 32B extends upward from the second semiconductor buffer layer 30B.

Each second semiconductor channel material nanosheet 20B is composed of an eleventh semiconductor material. In some embodiments, the eleventh semiconductor material that provides each second semiconductor channel material nanosheet 20B can provide high channel mobility for n-type FET devices (i.e., NFETs). In other embodiments, the eleventh semiconductor material that provides each second semiconductor channel material nanosheet 20B can provide high channel mobility for p-type FET devices (PFETs). The eleventh semiconductor material that provides each second semiconductor channel material nanosheet 20B can include one of the semiconductor materials mentioned above. In one example, the eleventh semiconductor material that provides each second semiconductor channel material nanosheet 20B is composed of silicon. In the present application, each second semiconductor channel material nanosheet 20B can be composed of a compositionally same, or compositionally different, semiconductor than each first semiconductor channel material nanosheet 20A.

Second gate structure 26B includes a second gate dielectric material and a second gate electrode, both of which are not separately shown, but intended to be within the region defined by the second gate structure 26B. The second gate dielectric material has a dielectric constant of 4.0 or greater, and includes one of the gate dielectric materials mentioned above for the first gate dielectric material of the first gat structure. In the present application, second gate dielectric material of the second gate structure 26B can be composed of a compositionally same, or compositionally different, gate dielectric material than the first gate dielectric material of the first gate structure 26A. The second gate electrode of the second gate structure 26B can include a work function metal (WFM) and optionally a conductive metal, as mentioned above for the first gate electrode of the first gate structure 26A. In the present application, second gate electrode of the second gate structure 26B can be composed of a compositionally same, or compositionally different, gate electrode material than the first electrode material of the first gate structure 26A.

Each second source/drain region 32B is composed of a twelfth semiconductor material and a second dopant. The twelfth semiconductor material can be compositionally the same as, or compositionally different from the eleventh semiconductor material that provides each second semiconductor channel material nanosheet 20B. The second dopant that is present in each second source/drain region 32B can be either a p-type dopant or an n-type dopant. In one embodiment, the second dopant that is present in each second source/drain region 32B is of an opposite conductivity type than the first dopant that is present in each first source/drain region 32A. In another embodiment, the second dopant that is present in each second source/drain region 32B is of same conductivity type as the first dopant that is present in each first source/drain region 32A. In one example, each second source/drain region 32B can have a dopant concentration of from 4×10²⁰ atoms/cm³ to 3×10²¹ atoms/cm³.

The second gate spacer 26B, the second inner spacer 28B and the second bottom dielectric isolation layer 18B are each composed of a spacer dielectric material, as defined above. In present application, the second gate spacer 26B and the second bottom dielectric isolation layer 18B are typically composed of a same spacer dielectric material.

The second backside source/drain contact placeholder structure 16B which is present in an upper portion of the second substrate (e.g., the second semiconductor device layer 14B) includes a thirteenth semiconductor material. The thirteenth semiconductor material is compositionally different from the ninth semiconductor material that provides the second semiconductor device layer 14B. In one example, thirteenth semiconductor material is a silicon germanium alloy. Note that the second backside source/drain contact placeholder structure 16B can extend above the topmost surface of the second semiconductor device layer 14B, but the height of the second backside source/drain contact placeholder structure 16B is typically less than, or equal to, a topmost surface of the second bottom dielectric isolation layer 18B.

If present, the second semiconductor buffer layer 30B is composed of a fourteenth semiconductor material that can be compositionally different from the thirteenth semiconductor material that provides the second backside source/drain contact placeholder structure 16B. The second semiconductor buffer layer 30B can be used as a growth surface for forming the second source/drain region 32B. Note that the second source/drain region 32B are typically formed by an epitaxial growth process and the presence of the second semiconductor buffer layer 30B facilitates the epitaxial growth of the second source/drain region 32B.

The second FET device FEOL level described above can be formed utilizing techniques (including nanosheet transistor formation techniques) well known to those skilled in the art. So as not to obscure any aspect of the present application details concerning the formation of the second FET device FEOL level are not provided herein.

The second FET device MOL level includes a second MOL dielectric layer 36B that includes at least one second FET device frontside source/drain contact structure 34B and at least one second MOL via contact structure 38B present therein. The second MOL dielectric layer 36B includes one or more ILD materials including those previous mentioned herein. The least one second FET device frontside source/drain contact structure 34B is composed of at least a contact conductor material, as defined previously herein. Each second FET device frontside source/drain contact structure 34B that is present contacts a second source/drain region 32A as shown in FIG. 2. The least one second MOL via contact structure 38B includes an electrically conductive metal or an electrically conductive metal alloy as defined above.

The second FET device MOL level described above can be formed utilizing techniques (including a metallization process) well known to those skilled in the art. So as not to obscure any aspect of the present application details concerning the formation of the second FET device MOL level are not provided herein.

Also present is the second FET device frontside BEOL structure 40B. The second FET device frontside BEOL structure 40B includes a second BEOL interconnect dielectric layer 46B having second FET device frontside BEOL metal wiring embedded therein. The second FET device frontside BEOL metal wiring includes first level interconnect lines 44B, a first combined interconnect wiring structure 45B (this includes a combination of one of the first level interconnect lines, an interconnect via structure and a second level interconnect line), nth level interconnect metal lines 48B (wherein n is greater than 3), a second combined interconnect structure 49B (this includes a combination of one of the nth level interconnect metal lines, an interconnect via and one of the uppermost interconnect lines 50B), and uppermost interconnect lines 50B.

The second BEOL interconnect dielectric layer 46B includes one or more interconnect dielectric materials as mentioned above. The second FET device frontside BEOL metal wiring is composed of an electrically conductive metal or an electrically conductive metal alloy, as defined above. Although not shown, a diffusion barrier liner can be present at least along the sidewall and optionally a bottom wall of the second FET device frontside BEOL metal wiring.

The second FET device frontside BEOL structure 40B described above can be formed utilizing techniques (including a BEOL process) well known to those skilled in the art. So as not to obscure any aspect of the present application details concerning the formation of the second FET device frontside BEOL structure 40B are not provided herein.

A carrier wafer 68 is typically present on the second FET device frontside BEOL structure 40B. The carrier wafer 68 can include a semiconductor material as defined above. Carrier wafer 68 is bonded to the second FET device frontside BEOL structure 40B utilizing any bonding process that is well known to those skilled in the art.

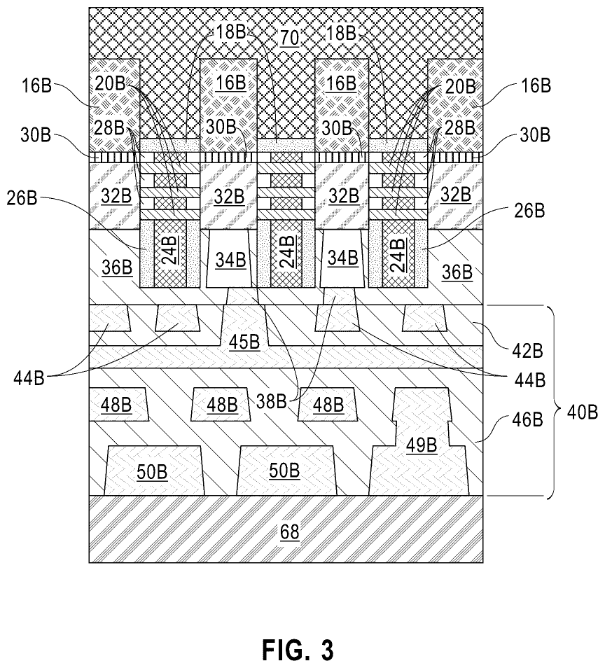

Referring now to FIG. 3, there is illustrated the exemplary second FET device of FIG. 2 after flipping the exemplary second FET device 180°, removing the substrate present in the second device FET FEOL level and forming a second FET device backside ILD layer. In the present application, the exemplary second FET device shown in FIG. 2 is flipped 180° to physically expose a backside of the second substate. This flipping step will allow backside processing of the exemplary second FET device. Backside processing occurs on a side of a substrate (or wafer) opposite the side where the transistors have been formed; in the present application the backside of the second substrate can be defined as the area of the second substrate that is beneath the second bottom dielectric isolation layer 18B. Flipping of the exemplary second FET device can be performed by hand or by utilizing a mechanical means such as, for example, a robot arm.

After flipping, the second substate can be removed (entirely or partially). The removal of the second substrate includes first removing the physically exposed second semiconductor base layer 10B; this removal step can be omitted in embodiments in which no second semiconductor base layer 10B is present in the second substrate. The removal of the second semiconductor base layer 10B can be performed utilizing a material removal process that is selective in removing the semiconductor material that provides the second semiconductor base layer 10B. The removal of the second semiconductor base layer 10B physically exposed the second etch stop layer 12B of the second substrate. The physically exposed second etch stop layer 12B can then be removed; this removal step can be omitted in embodiments in which no second etch stop layer 12B is present in the second substrate. The removal of the second etch stop layer 12B can be performed utilizing a material removal process that is selective in removing the material that provides the second etch stop layer 12B.

The removal of the second etch stop layer 12B physically exposes the second semiconductor device layer 14B. The second semiconductor device layer 14B can be removed to reveal the second backside source/drain contact placeholder structures 16B. The removal of the second semiconductor device layer 14B can be performed utilizing a material removal process that is selective in removing the semiconductor material that provides the second semiconductor device layer 14B. In some embodiments, an entirety of the second semiconductor device layer 14B is removed as is shown in FIG. 3. In other embodiments, a portion of the second semiconductor device layer 14B is removed, while maintaining a thin portion of the second semiconductor device layer 14B on the second bottom dielectric isolation layer 18B.

Next, the second FET device backside ILD layer 70 is formed. The second FET device backside ILD layer 70 is formed so as to embed the revealed second backside source/drain contact placeholder structures 16B. The second FET device backside ILD layer 70 can include one of the ILD materials mentioned previously herein. The second FET device backside ILD layer 70 can be formed by a deposition process (such as, for example, chemical vapor deposition (CVD), plasma enhanced chemical vapor deposition (PECVD) or spin-on coating. A planarization process such as, for example, chemical mechanical polishing (CMP) can sometimes follow the deposition of the second FET device backside ILD layer 70.

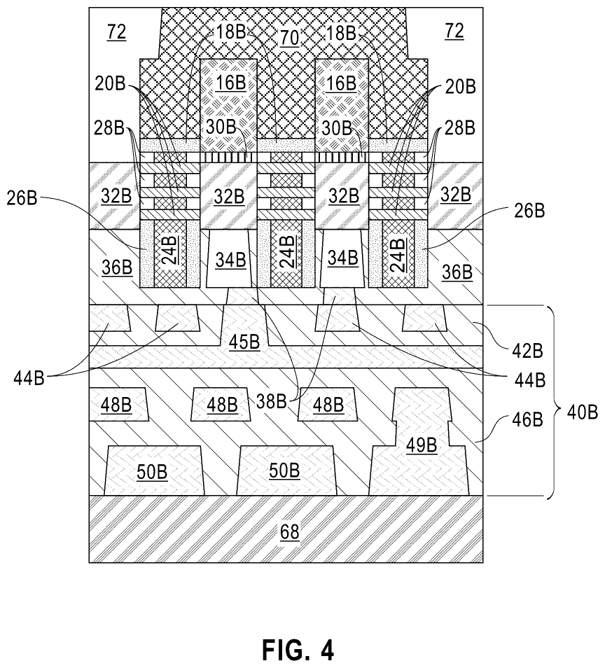

Referring now to FIG. 4, there is illustrated the exemplary second FET device of FIG. 3 after forming second FET device backside source/drain contact structures 72 in the second FET device backside ILD layer 70. The second FET device backside source/drain contact structures 72 can be formed by first removing each second backside source/drain contact placeholder structure 16B that contacts (either directly or indirectly) a second source/drain region 32B that was not previous connected to one of the second FET device frontside source/drain contact structures 34B. The removal of these second backside source/drain contact placeholder structures 16B includes forming backside source/drain contact openings in the second FET device backside ILD layer 70. The backside source/drain contact openings can be formed by lithography and etching (dry etching and/or wet etching). Dry etching can include, for example, reactive ion etching (RIE), ion beam etching (IBE), and plasma etching. Wet etching includes the use of an appropriate chemical etchant that has a high etch rate for one material as compared to at least one another material. Each backside source/drain contact opening physically exposes one of the second backside source/drain contact placeholder structures 16B that contacts (either directly or indirectly) a second source/drain region 32B that was not previous connected to one of the second FET device frontside source/drain contact structures 34B. The physically exposed second backside source/drain contact placeholder structures 16B can be removed utilizing a selective etching process. The selective etching process that removes the physically exposed second backside source/drain contact placeholder structures 16B can physically expose the second semiconductor buffer layer 30B (if the same is present) or the second source/drain regions 32A that were not previously connected to a one of the second FET device frontside source/drain contact structures 34B. The physically exposed second semiconductor buffer layer 30B is then removed utilizing a selective etch so as to physically exposed the second source/drain regions 32A that were not previously connected to a one of the second FET device frontside source/drain contact structures 34B. After removing the second semiconductor buffer layer 30B, a metallization process can be used to form at least a contact conductor material, as defined previously herein in the each of the backside source/drain contact openings that have been extended to physically exposed the second the second source/drain regions 32A that were not previously connected to a one of the second FET device frontside source/drain contact structures 34B. The metallization process includes deposition of at least the contact conductor material in each of these extended backside source/drain contact openings. A planarization process including CMP can typically follow the deposition of the at least the contact conductor material. This metallization process forms the second FET device backside source/drain contact structures 72.

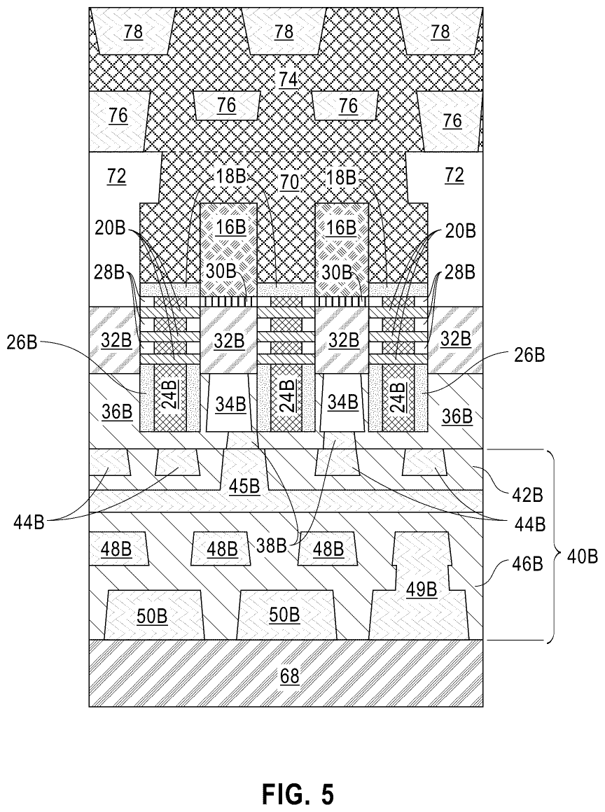

Referring now to FIG. 5, there is illustrated the exemplary second FET device of FIG. 4 after forming additional second FET device backside ILD layers 74 with second FET device power lines (i.e., lower power second FET device power lines 76 and upper second FET device power lines 78) embedded therein. In accordance with the present application, the additional second FET device backside ILD layers 74 and the second device FET backside power lines (i.e., lower second FET device power lines 76 and upper second FET device power lines 78) collectively form a second FET device backside power distribution network.

The additional second FET device backside ILD layers 74 can include one of the ILD materials mentioned previously herein. The additional second FET device backside ILD layers 74 can be formed by a deposition process such as, for example, CVD, PECVD or spin-on coating.

The second FET device power lines (i.e., lower second FET device power lines 76 and upper second FET device power lines 78) are composed of electrically conductive power line material. The electrically conductive power line material includes, but is not limited to, W, Co, Ru, Al, Cu, Pt, Rh, or Pd. A thin metal adhesion layer, such as TiN, TaN, etc. can be also formed along a sidewall and bottom wall of each of the second FET device power lines. The second FET device power lines (including the lower second FET device power lines 76 and upper second FET device power lines 78) can be formed by a metallization process in which a backside power line opening(s) is (are) formed in one of the second FET device backside ILD layers of the additional second FET device backside ILD layers 74 by lithography and etching, and then the backside power line opening(s) is (are) filled with an electrically conductive power line material as defined above. A planarization is the performed to provide the second FET device power lines. In the present application, some of the lower second FET device power lines 76 are in electrical contact with the second FET device backside source/drain contact structures 72.

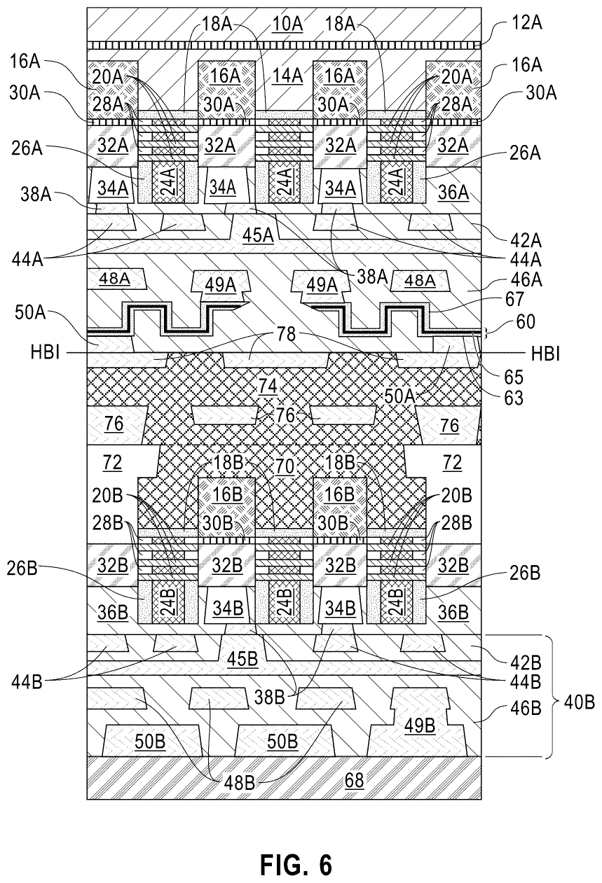

Referring now to FIG. 6, there is illustrated a hybrid bonded structure that is formed after bonding the first FET device frontside BEOL structure 40A of the first FET device to the second FET device backside power distribution network utilizing a hybrid bonding process. In the present, and after hybrid bonding, the first FET device is can be referred to as a top FET device, while the second FET device can be referred to a bottom FET device. The hybrid bonding process includes flipping the exemplary first FET device shown in FIG. 1A 180° such that the first FET device frontside BEOL structure 40A of the first FET device faces the second FET device backside power distribution network of the exemplary second FET device shown in FIG. 5. After flipping, the first FET device is aligned over the second FET device such that the uppermost BEOL lines 50A of the first FET device is aligned over the upper second FET device power lines 78 of the second FET device. The aligned first FET device is then brought into intimate contact with each other. The bringing the aligned first FET device into intimate contact with the second FET device can include the application of an external force which may or may not remain during the heating step. After aligning and contacting, the hybrid bonding process continues by heating the aligned and contacted first FET device and second FET device from room temperature (i.e., 20° C.-25° C.) up to 450° C.; temperatures greater than 450° C. can also be used in the present application. The heating step is typically performed in an inert ambient such as, for example, He, Ar, Ne or mixtures thereof. The heating steps bonds the first FET device and second FET device together and provides a hybrid bonding interface HBI between the first FET device and second FET device. After bonding, the temperature can be lowered back to room temperature. The hybrid bonding process can also include an activation process as described above.

At the hybrid bonding interface HBI, bonding occurs between the uppermost BEOL lines 50A of the first FET device and the upper second FET device power lines 78 of the second FET device. Notably, a metal-to-metal bond forms between the uppermost BEOL lines 50A of the first FET device and the upper second FET device power lines 78 of the second FET device. This metal-to-metal bond electrically connects the uppermost BEOL lines 50A of the first FET device and the upper second FET device power lines 78 of the second FET device at the hybrid bonding interface. Also, and since first BEOL interconnect dielectric region 46A of the first FET device bonds with the second FET device backside ILD region 74 at the hybrid bonding interface, a dielectric-to-dielectric bond is also formed. After hybrid bonding the at least one capacitor 60 is connected to the second FET device. This connection occurs at the hybrid bonding interface and is via a hybrid bond formed between one of the uppermost BEOL lines 50A of the first FET device and one of the upper second FET device power lines 78 of the second FET device backside power distribution network.

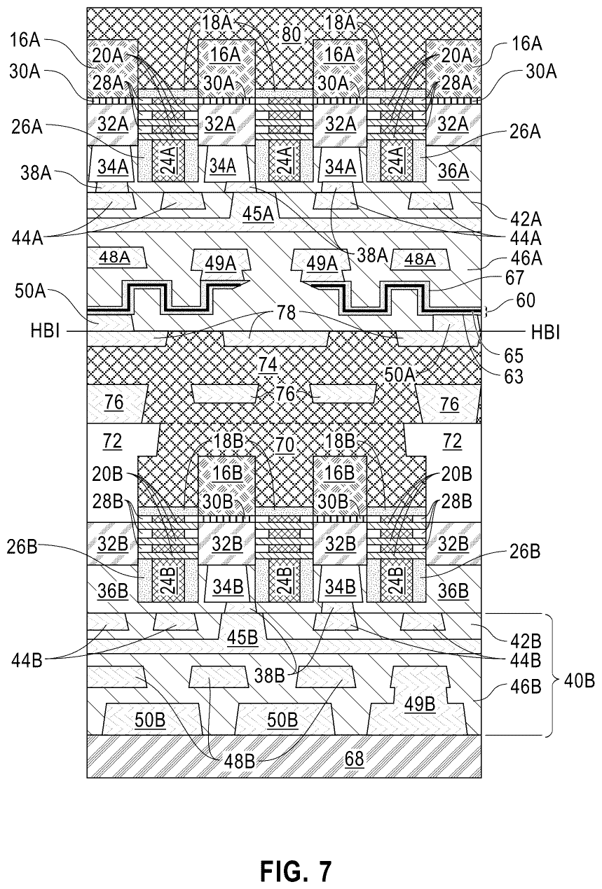

Referring now to FIG. 7, there is illustrated the hybrid bonded structure illustrated in FIG. 6 after removing (entirely or partially) the first substrate present in the first FET device FEOL level and forming a first FET device backside ILD layer 80. The removal of the first substrate includes first removing the physically exposed first semiconductor base layer 10A; this removal step can be omitted in embodiments in which no first semiconductor base layer 10A is present in the second substrate. The removal of the first semiconductor base layer 10A can be performed utilizing a material removal process that is selective in removing the semiconductor material that provides the first semiconductor base layer 10A. The removal of the first semiconductor base layer 10A physically exposed the first etch stop layer 12A of the first substrate. The physically exposed first etch stop layer 12A can then be removed; this removal step can be omitted in embodiments in which no first etch stop layer 12A is present in the second substrate. The removal of the first etch stop layer 12A can be performed utilizing a material removal process that is selective in removing the material that provides the first etch stop layer 12A.

The removal of the first etch stop layer 12A physically exposes the first semiconductor device layer 14A. The first semiconductor device layer 14A can be removed to reveal the first backside source/drain contact placeholder structures 16A. The removal of the first semiconductor device layer 14A can be performed utilizing a material removal process that is selective in removing the semiconductor material that provides the first semiconductor device layer 14A. In some embodiments, an entirety of the first semiconductor device layer 14A is removed as is shown in FIG. 7. In other embodiments, a portion of the first semiconductor device layer 14A is removed, while maintaining a thin portion of the first semiconductor device layer 14A on the first bottom dielectric isolation layer 18A.

Next, the first FET device backside ILD layer 80 is formed. The first FET device backside ILD layer 80 is formed so as to embed the revealed first backside source/drain contact placeholder structures 16A, The first FET device backside ILD layer 80 can include one of the ILD materials mentioned previously herein. The first FET device backside ILD layer 80 can be formed by a deposition process such as, for example, CVD, PECVD or spin-on coating. A planarization process such as, for example, chemical mechanical polishing (CMP) can sometimes follow the deposition of the first FET device backside ILD layer 80.

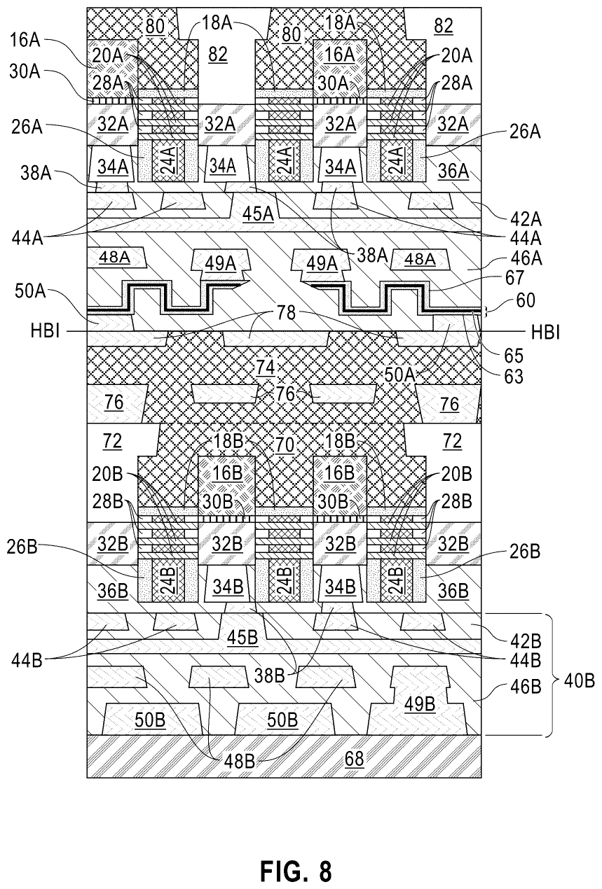

Referring now to FIG. 8, there is illustrated the hybrid bonded structure illustrated in FIG. 7 after forming first FET device backside source/drain contact structures 82 in the first FET device backside ILD layer 80. The first FET device backside source/drain contact structures 82 can be formed by first removing each first backside source/drain contact placeholder structure 16A that contacts (either directly or indirectly) a first source/drain region 32A that was not previous connected to one of the first MOL via contact structures 38A. The removal of these first backside source/drain contact placeholder structures 16A includes forming backside source/drain contact openings in the first FET device backside ILD layer 80. The backside source/drain contact openings can be formed by lithography and etching (dry etching and/or wet etching). Each backside source/drain contact opening physically exposes one of the first backside source/drain contact placeholder structures 16A that contacts (either directly or indirectly) a first source/drain region 32A that was not previous connected to one of the first MOL via contact structures 38A. The physically exposed first backside source/drain contact placeholder structures 16A can be removed utilizing a selective etching process. The selective etching process that removes the physically exposed first backside source/drain contact placeholder structures 16A can physically expose the first semiconductor buffer layer 30A (if the same is present) or the first source/drain regions 32A that were not previously connected to a one of the first MOL via contact structures 38A. The physically exposed first semiconductor buffer layer 30A is then removed utilizing a selective etch so as to physically exposed the first source/drain regions 32A that were not previously connected to a one of the first MOL via contact structures 38A. After removing the first semiconductor buffer layer 30A, a metallization process as defined above in forming the second FET device backside source/drain contact structures 72 can be used in forming the first FET device backside source/drain contact structures 82. The first FET device backside source/drain contact structures 82 are composed of at least a contact conductor material, as defined previously herein.

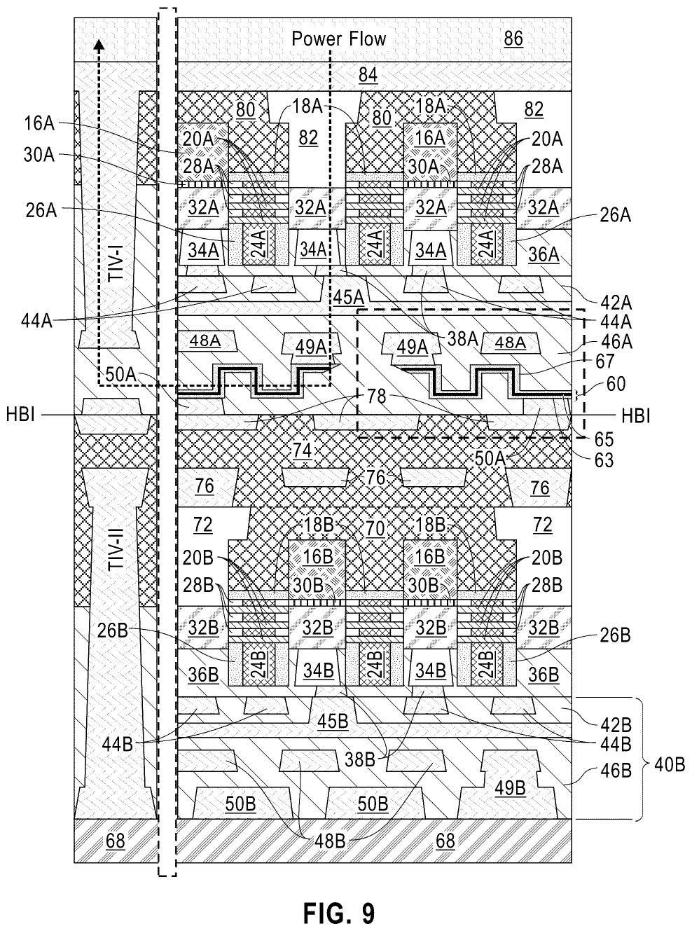

Referring now to FIG. 9, there is illustrated the hybrid bonded structure shown in FIG. 8 after forming a first FET device backside power line 84 and a first FET backside power distribution network 86 on the first FET device backside ILD layer 80. The first FET device backside power line 84 is in electrically contact with the first FET device backside power line 84 and the first FET backside power distribution network 86. The first FET device backside power line 84 can be composed of a, electrically conductive power line material as defined above for the second FET device power lines (i.e., lower second FET device power lines 76 and upper second FET device power lines 78). The first FET device backside power line 84 can be formed utilizing the technique mentioned above in forming the second FET device power lines.

The first FET device backside power distribution network 86 is composed of electrically conductive metal wires that are embedded in one or more ILD layers. The first FET device backside power distribution network 86 can be formed utilizing techniques well known to those skilled in the art.

In embodiments of the present application, the at least one capacitor 60 is connected to the second FET device at the hybrid bonding interface by a hybrid bond formed between uppermost BEOL line 50A present in the first FET device frontside BEOL structure 40A of the first FET device and an upper second FET device power line 78 present in the second FET device backside power distribution network. In some embodiments of the present application, the at least one capacitor (i.e., capacitor 60 on the left hand side of FIG. 9 is configured for power delivery and is electrically connected to the first FET device backside power distribution network and the second FET device backside power distribution network. In other embodiments, the at least one capacitor (i.e., capacitor 60 on the right hand side and within the boxed region of FIG. 9) is configured for analog applications and is electrically connected to uppermost BEOL line 50A present in the first FET device frontside BEOL structure 48A and to an upper second FET device power line 78 present in the second FET device backside power distribution network. In other embodiments, the at least one capacitor includes a first capacitor configured for power delivery (i.e., capacitor 60 on the left hand side of FIG. 9) and a second capacitor (i.e., capacitor 60 on the right hand side and in the boxed region of FIG. 9) configured for analog application. In such an embodiment, the first capacitor is electrically connected to the first FET device backside power distribution network and the second FET device backside power distribution network, and the second capacitor is electrically connected to uppermost BEOL line 50A present in the first FET device frontside BEOL structure 40A and to an upper second FET device power line 78 present in the second FET device backside power distribution network.

Also shown in FIG. 9 is a region of the first FET device in which a first FET device through dielectric via (TIV-I) is present and a region of the second FET device in which a second FET device through dielectric via (TIV-II) is present. TIV-I and TIV-II are composed of an electrically conductive metal or electrically conductive metal as defined above. TIV-I and TIV-II are formed utilizing techniques well known to those skilled in the art. As is shown, TIV-I and TIV-II pass through various dielectric material layers (i.e., ILD) of the first FET device and the second FET device, respectively. TIV-I and TIV-II are depicted as tall vias that may skip adjacent metal layers. Although such a possibilities exists for TIV-I and TIV-II, the present application is not limited to the same. Instead, the TIVs can include stack of vias and lines. Also, it is possible that the TIVs are adjacent only to the device layer and that there are standard BEOL layers connected to the TIVs.

In FIG. 9, power can be transferred from the first FET device backside power distribution network 86 in the direction as shown. Notably, the power flows from the first FET device backside power distribution network 86 into the first FET device backside power line 84, and then into one of the first nanosheet transistors of the first device region via the electrically connected first FET device backside source/drain contact structure 82-first source/drain region 32A, and first FET device frontside source/drain contact structure 34A. Power flow continues from the electrically connected first FET device backside source/drain contact structure 82-first source/drain region 32A, and first FET device frontside source/drain contact structure 34A into the first combined BEOL wiring structure 45A. The power flow then continues to the capacitor 60 (shown on the FET left side of FIG. 9), and thereafter the power can flow into the second FET device and into the TIV-I. In FIG. 9, the dotted box on the right hand side of the drawing illustrates a MIM capacitor 60 between a Vss power line (e.g., upper second FET device power line 78) and a BEOL signal (e.g., uppermost BEOL line 50A) for analog applications; through the present application analog applications can include AI analog applications and non-AI applications. Although such a power flow is described and illustrated, the present application, can have alternative power flows.

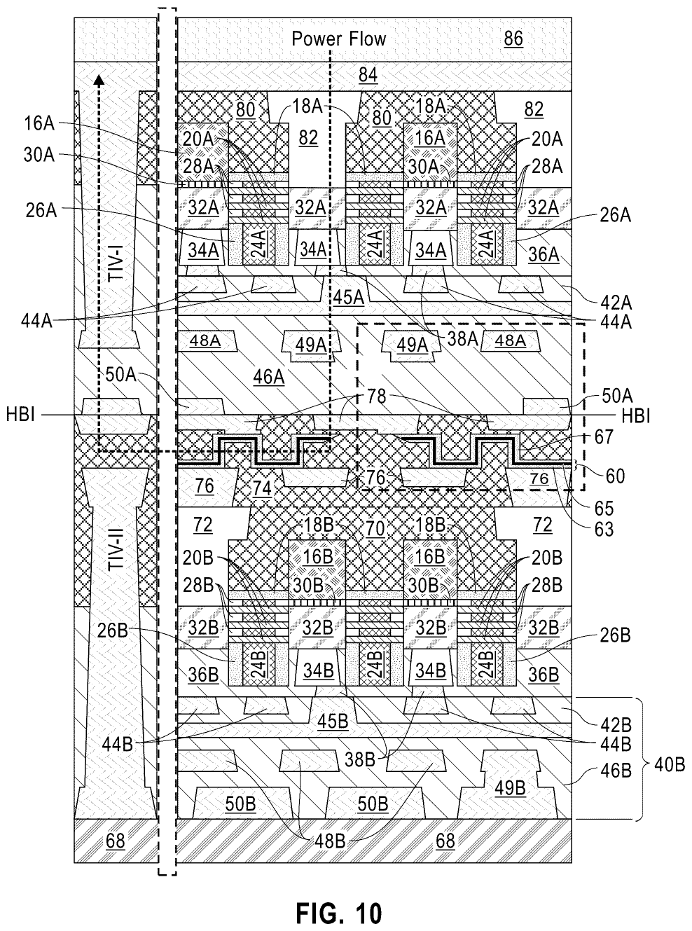

Referring now to FIG. 10, there is illustrated an alternative hybrid bonded structure including a first FET device stacked above a second FET device in which the second FET device includes the at least one capacitor 60 instead of the first FET device as is shown in the hybrid bonded structure of FIG. 9. The alternative hybrid bonded structure shown in FIG. 10 includes elements/components as mentioned above for the hybrid bonded structure illustrated in FIG. 9. The alternative hybrid bonded structure shown in FIG. 10 can be formed utilizing the technique mentioned above except that the capacitors 60 are formed in an upper region of the second FET device backside ILD region 74 of the second FET device backside power distribution network. Although such a power flow is described and illustrated, the present application, can have alternative power flows

In embodiments of the present application, the at least one capacitor 60 is connected to the second FET device at the hybrid bonding interface by a hybrid bond formed between uppermost BEOL line 50A present in the first FET device frontside BEOL structure 40A of the first FET device and an upper second FET device power line 78 present in the second FET device backside power distribution network. In some embodiments of the present application, the at least one capacitor (i.e., capacitor 60 on the left hand side of FIG. 10 is configured for power delivery and is electrically connected to the first FET device backside power distribution network and the second FET device backside power distribution network. In other embodiments, the at least one capacitor (i.e., capacitor 60 on the right hand side and within the boxed region of FIG. 10) is configured for analog applications and is electrically connected to uppermost BEOL line 50A present in the first FET device frontside BEOL structure 48A and to an upper second FET device power line 78 present in the second FET device backside power distribution network. In other embodiments, the at least one capacitor includes a first capacitor configured for power delivery (i.e., capacitor 60 on the left hand side of FIG. 10) and a second capacitor (i.e., capacitor 60 on the right hand side and in the boxed region of FIG. 10) configured for analog application. In such an embodiment, the first capacitor is electrically connected to the first FET device backside power distribution network and the second FET device backside power distribution network, and the second capacitor is electrically connected to uppermost BEOL line 50A present in the first FET device frontside BEOL structure 40A and to an upper second FET device power line 78 present in the second FET device backside power distribution network.

In FIG. 10, power can be transferred from the first FET device backside power distribution network 86 in the direction as shown. Notably, the power flows from the first FET device backside power distribution network 86 into the first FET device backside power line 84, and then into one of the first nanosheet transistors of the first device region via the electrically connected first FET device backside source/drain contact structure 82-first source/drain region 32A, and first FET device frontside source/drain contact structure 34A. Power flow continues from the electrically connected first FET device backside source/drain contact structure 82-first source/drain region 32A, and first FET device frontside source/drain contact structure 32A into the first combined BEOL wiring structure 45A. The power flow then continues to the capacitor 60 (shown on the left hand side of FIG. 10), and thereafter the power can flow into the TIV-I. In FIG. 10, the dotted box on the right hand side of the drawing illustrates a capacitor 60 between a Vss power line (e.g., upper second FET device power line 78) and a BEOL signal (e.g., uppermost BEOL line 50A) for analog applications; through the present application analog applications can include AI analog applications and non-AI applications. Although such a power flow is described and illustrated, the present application, can have alternative power flows

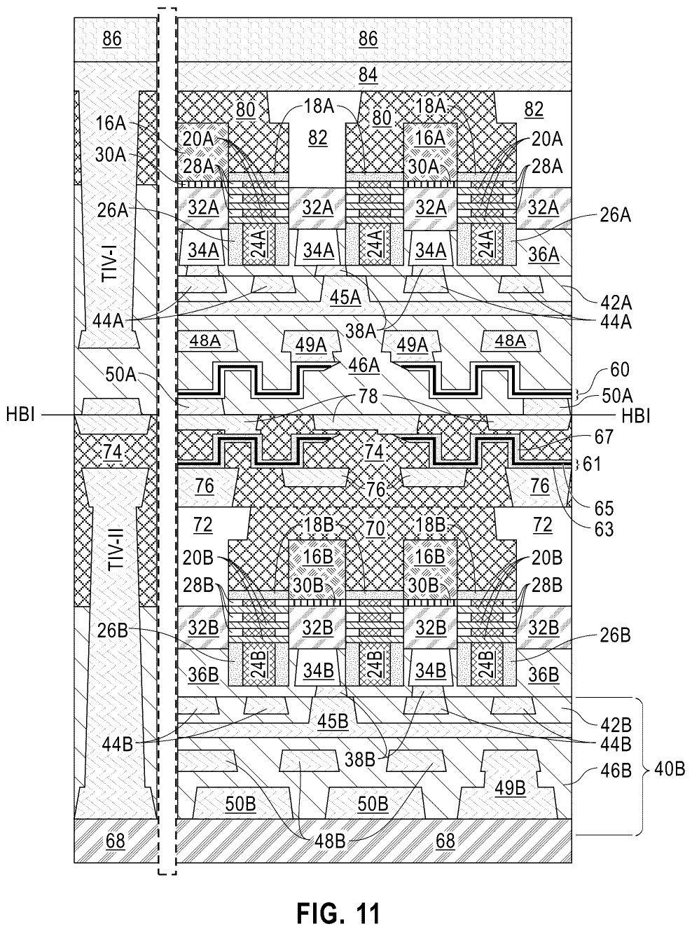

Referring now to FIG. 11 is a cross sectional view of another alternative hybrid bonded structure including a first FET device stacked above a second FET device in which the first FET device includes the at least one capacitor 60 and the second FET device includes at least one decoupling capacitor 61. Each decoupling capacitor 61 is composed of a third metal layer 63, a decoupling capacitor dielectric layer 65, and a fourth metal layer 67. The third metal layer 63 is composed of a third conductive metal-containing material, while the fourth metal layer 67 is composed of a fourth conductive metal-containing material. The third conductive metal-containing material can be compositionally the same as, or compositionally different from, the fourth conductive metal-containing material. Illustrative conductive metal-containing materials that can be used in providing the third metal layer 63 and the fourth metal layer 67 include, but are not limited to, titanium nitride and/or tantalum nitride. The decoupling capacitor dielectric layer 65 is composed of a dielectric material such as, for example, one of the high k gate dielectric materials mentioned above. Each decoupling capacitor 61 can be a MIM decoupling capacitor having a meandering (or serpentine) pattern to increase the overall surface area of the capacitor. Each decoupling capacitor 61 can be formed utilizing techniques well known in the art. Note that each decoupling capacitor 61 is configured for analog to digital conversion and is electrically connected to a source/drain region of a FET of the second FET device and to the at least one capacitor 60 present in the first FET device frontside BEOL structure 40A. It is noted that the decoupling capacitor 61 is not limited to the one described above. Instead, other decoupling capacitors are contemplated and can be employed herein including, for example, decoupling capacitors having greater than two plates, and/or those include plates having single or multi-metal stacks, and/or those having multilayered dielectric stacks

In embodiments of the present application, the at least one capacitor 60 is connected to the second FET device at the hybrid bonding interface by a hybrid bond formed between uppermost BEOL line 50A present in the first FET device frontside BEOL structure 40A of the first FET device and an upper second FET device power line 78 present in the second FET device backside power distribution network. In some embodiments of the present application, the at least one capacitor (i.e., capacitor 60 on the left hand side of FIG. 11 is configured for power delivery and is electrically connected to the first FET device backside power distribution network and the second FET device backside power distribution network. In other embodiments, the at least one capacitor (i.e., capacitor 60 on the right hand side and within the boxed region of FIG. 11) is configured for analog applications and is electrically connected to uppermost BEOL line 50A present in the first FET device frontside BEOL structure 48A and to an upper second FET device power line 78 present in the second FET device backside power distribution network. In other embodiments, the at least one capacitor includes a first capacitor configured for power delivery (i.e., capacitor 60 on the left hand side of FIG. 11) and a second capacitor (i.e., capacitor 60 on the right hand side and in the boxed region of FIG. 11) configured for analog application. In such an embodiment, the first capacitor is electrically connected to the first FET device backside power distribution network and the second FET device backside power distribution network, and the second capacitor is electrically connected to uppermost BEOL line 50A present in the first FET device frontside BEOL structure 40A and to an upper second FET device power line 78 present in the second FET device backside power distribution network.

Although not shown, it is possible to flip the located of the at least one capacitor 60 and the at least one decoupling capacitor 61 such that the at least one capacitor 60 is present in the second FET device backside power distribution network and the at least one decoupling capacitor is present in the first FET device frontside BEOL structure 40A.

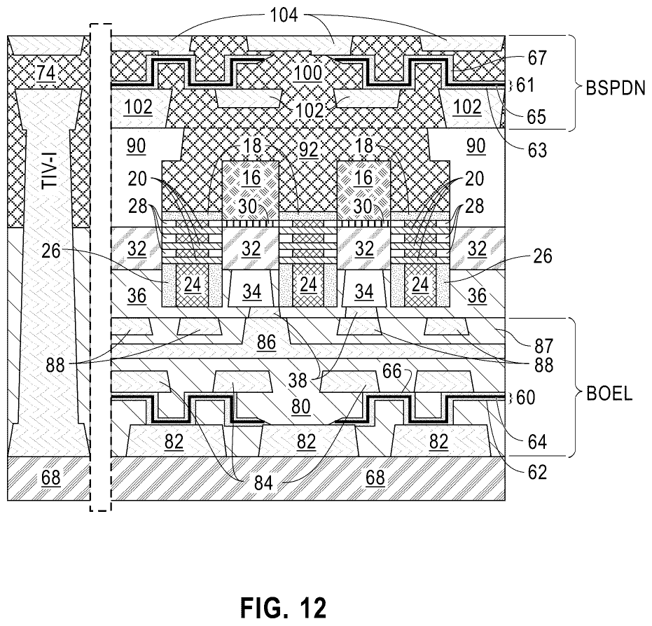

Referring now to FIG. 12, there is illustrated an exemplary device including a FET device including at least one decoupling capacitor located on the backside and at least one capacitor located on the frontside. Notably, the semiconductor device includes a frontside BEOL structure (labeled as BEOL in FIG. 12) located on a frontside of a FEOL level containing at least one FET, and a backside power distribution network (labeled as BSPDN in FIG. 12) located on a backside of the FEOL level. The semiconductor device further includes at least one capacitor 60 embedded in the frontside BEOL structure that is electrically connected to an upper frontside BEOL line 84 and a lower frontside BEOL line 82, and at least one decoupling capacitor 61 embedded in the backside power distribution network that is electrically connected to a backside power line 104 of the backside power distribution network and a source/drain region 32 of the at least one FET via lower backside power line 102.

In this embodiment, the FEOL level can also include a gate spacer 26, an inner spacer 28, a bottom dielectric isolation layer 18, a backside source/drain contact placeholder structure 16, and a semiconductor buffer layer 30, as is shown in FIG. 12. Each of these elements includes materials as defined above so similar elements shown in FIG. 1. In some embodiments, the bottom dielectric isolation layer 18 and/or the semiconductor buffer layer 30 can be omitted from the device FEOL level. In the illustrated embodiment, the at least FET is a nanosheet transistor includes a vertical stack of semiconductor material nanosheets 20, a gate structure 24 contacting each of the nanosheets, and a source/drain region 32 located on each side of the gate structure 24. Each of these elements includes materials as defined above so similar elements shown in FIG. 1.

As is shown in FIG. 12, a MOL level is located between the FEOL level and the BEOL structure. The MOL level includes MOL dielectric layer 36 which includes at least one frontside source/drain contact structure 34 and at least one MOL via contact structure 38 embedded therein. The at least one frontside source/drain contact structure 34 is in electrically contact with one of the source/drain regions 32 of the at least one FET.

The BEOL structure includes a BEOL interconnect dielectric region 80 that includes at least one capacitor 60 as defined above, upper frontside BEOL lines 84, lower frontside BEOL lines 82, a combined BEOL wiring structure 86, and BEOL wiring 88. Carrier wafer 68 is also shown in contact with the BEOL structure.

The BSPDN includes a backside ILD region 100 that includes the at least one decoupling capacitor 61, as defined above, backside power lines 104, and lower backside power lines 102 embedded therein. Note that the backside power lines 104 contact an upper surface of the at least one decoupling capacitor 61, and the lower backside power lines 102 contacts a lower surface of the at least one decoupling capacitor 61. At least one of lower backside power lines 102 contacts a backside source/drain contact structure 90 as shown in FIG. 12. Thus, the at least one decoupling capacitor 61 is electrically connected to the at least one FET from the backside of the device.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first field effect transistor (FET) device comprising a first FET device frontside back-end-of-the-line (BEOL) structure located on a frontside of a first FET device front-end-of-the-line (FEOL) level containing at least one first FET, and a first FET device backside power distribution network located on a backside of the first FET device FEOL level, wherein the first FET device frontside BEOL structure comprises at least one capacitor embedded therein; and
a second FET device comprising a second FET device frontside BEOL structure located on a frontside of a second FET device FEOL level, and a second FET device backside power distribution network located on a backside of the second FET device FEOL level containing at least one second FET, wherein the first FET device is stacked above the second FET device and the first FET device frontside BEOL structure forms a hybrid bonding interface with the second FET device backside power distribution network and wherein the at least one capacitor is connected to the second FET device at the hybrid bonding interface.

2. The semiconductor device of claim 1, wherein the at least one capacitor is connected to the second FET device at the hybrid bonding interface by a hybrid bond formed between an uppermost BEOL line present in the first FET device frontside BEOL structure of the first FET device and an upper second FET device power line present in the second FET device backside power distribution network.

3. The semiconductor device of claim 1, wherein the at least one capacitor is configured for power delivery and is electrically connected to the first FET device backside power distribution network and the second FET device backside power distribution network.

4. The semiconductor device of claim 1, wherein the at least one capacitor is configured for analog applications and is electrically connected to uppermost BEOL line present in the first FET device frontside BEOL structure and to an upper second FET device power line present in the second FET device backside power distribution network.

5. The semiconductor device of claim 1, wherein the at least one capacitor comprises a first capacitor configured for power delivery and a second capacitor configured for analog application, wherein the first capacitor is electrically connected to the first FET device backside power distribution network and the second FET device backside power distribution network, and the second capacitor is electrically connected to uppermost BEOL line present in the first FET device frontside BEOL structure and to an upper second FET device power line present in the second FET device backside power distribution network.

6. The semiconductor device of claim 1, wherein the at least one capacitor comprises a metal-insulator-metal capacitor (MIM) capacitor.

7. The semiconductor device of claim 1, further comprising at least one decoupling capacitor embedded in the second FET device power distribution network of the second FET device.

8. The semiconductor device of claim 7, wherein the at least one decoupling capacitor is configured for analog to digital conversion and is electrically connected to a source/drain region of the second FET of the second FET device and to the at least one capacitor present in the first FET device frontside BEOL structure.

9. The semiconductor device of claim 7, wherein the at least one decoupling capacitor comprises a MIM decoupling capacitor.

10. A semiconductor device comprising:
a first FET device comprising a first FET device frontside back-end-of-the-line (BEOL) structure located on a frontside of a first FET device front-end-of-the-line (FEOL) level containing at least one first FET, and a first FET device backside power distribution network located on a backside of the first FET device FEOL level; and
a second FET device comprising a second FET device frontside BEOL structure located on a frontside of a second FET device FEOL level, and a second FET device backside power distribution network located on a backside of the second FET device FEOL level containing at least one second FET, wherein the first FET device is stacked above the second FET device, the first FET device frontside BEOL structure forms a hybrid bonding interface with the second FET device FET device backside power distribution network, and the second FET device power distribution network comprises at least one capacitor embedded therein, wherein the at least one capacitor is connected to the first FET device at the hybrid bonding interface.

11. The semiconductor device of claim 10, wherein the at least one capacitor is connected to the second FET device at the hybrid bonding interface by a hybrid bond formed between an uppermost BEOL line present in the first FET device frontside BEOL structure of the first FET device and an upper second FET device power line present in the second FET device backside power distribution network.

12. The semiconductor device of claim 10, wherein the at least one capacitor is configured for power delivery and is electrically connected to the first FET device backside power distribution network and to the second FET device backside power distribution network.

13. The semiconductor device of claim 10, wherein the at least one capacitor is configured for analog applications and is electrically connected to uppermost BEOL line present in the first FET device frontside BEOL structure and to an upper second FET device power line present in the second FET device backside power distribution network.

14. The semiconductor device of claim 10, wherein the at least one capacitor comprises a first capacitor configured for power delivery and a second capacitor configured for analog application, wherein the first capacitor is electrically connected to the first FET device backside power distribution network and the second FET device backside power distribution network, and the second capacitor is electrically connected to uppermost BEOL line present in the first FET device frontside BEOL structure and to an upper second FET device power line present in the second FET device backside power distribution network.

15. The semiconductor device of claim 10, wherein the at least one capacitor comprises a metal-insulator-metal capacitor (MIM) capacitor.

16. A semiconductor device comprising:
a frontside back-end-of-the-line (BEOL) structure located on a frontside of a front-end-of-the-line (FEOL) level containing at least one FET, and a backside power distribution network located on a backside of the FEOL level;
at least one capacitor embedded in the frontside BEOL structure and is electrically connected to an upper frontside BEOL line and a lower frontside BEOL line; and
at least one decoupling capacitor embedded in the backside power distribution network and electrically connected to a backside power line of the backside power distribution network and a source/drain region of the at least one FET.
